(19) United States
(12) Patent Application Publication
(10) Pub. No.: US 2012/0290255 A1
(43) Pub. Date: Nov. 15, 2012

(54) CLEAR LAYER ISOLATION

(75) Inventors: Nikhil Vishwanath Kelkar, Saratoga, CA (US); Viraj Ajit Patwardhan, Milpitas, CA (US); Santhiran Nadarajah, Chemor (MY); Matt Preston, San Jose, CA (US)

(73) Assignee: Intersil Americas Inc., Milpitas, CA (US)

(21) Appl. No.: 13/237,489

(22) Filed: Sep. 20, 2011

Related U.S. Application Data
(60) Provisional application No. 61/485,967, filed on May 13, 2011.

(51) Int. Cl. G01B 11/00; H01L 31/12; H01L 33/48

(52) U.S. Cl. 702/150; 438/25; 257/84; 257/E31.096; 257/E33.076

(57) ABSTRACT

A method for optical isolation in a clear mold package is provided. The method comprises forming a substrate and mounting a first component on the substrate. The method also comprises depositing a clear layer over the first component and the substrate and fabricating a trench in the clear layer near the first component, wherein the trench extends from a top surface of the substrate to the top surface of the clear layer. Further, the method comprises depositing an opaque material within the trench.

### CROSS REFERENCE TO RELATED APPLICATIONS

This application claims the benefit of priority to U.S. Provisional Application No. 61/485,967, filed on May 13, 2011, the disclosure of which is incorporated herein by reference.

### DRAWINGS

Understanding that the drawings depict only exemplary embodiments and are not therefore to be considered limiting in scope, the exemplary embodiments will be described with additional specificity and detail through the use of the accompanying drawings in which:

FIG. 1 is a block diagram of a proximity sensor according to one embodiment.

FIG. 2A-2D are block diagrams illustrating the fabrication of a device using clear layer isolation according to one embodiment.

FIGS. 3A-3B are illustrations of a plurality of devices fabricated implementing isolation in a clear layer according to one embodiment.

FIG. 4 is an illustration of the fabrication of a device implementing isolation in a clear layer according to one embodiment.

FIG. 5 is a block diagram illustrating a system using a proximity sensor.

FIG. 6 is a flow diagram of a method for isolating electrical components in a clear layer according to one embodiment.

In accordance with common practice, the various described features are not drawn to scale but are drawn to emphasize specific features relevant to the exemplary embodiments.

### DETAILED DESCRIPTION

In the following detailed description, reference is made to the accompanying drawings that form a part hereof, and in which is shown by way of illustration specific illustrative embodiments. However, it is to be understood that other embodiments may be utilized and that logical, mechanical, and electrical changes may be made. Furthermore, the method presented in the drawing figures and the specification is not to be construed as limiting the order in which the individual acts may be performed. The following detailed description is, therefore, not to be taken in a limiting sense.

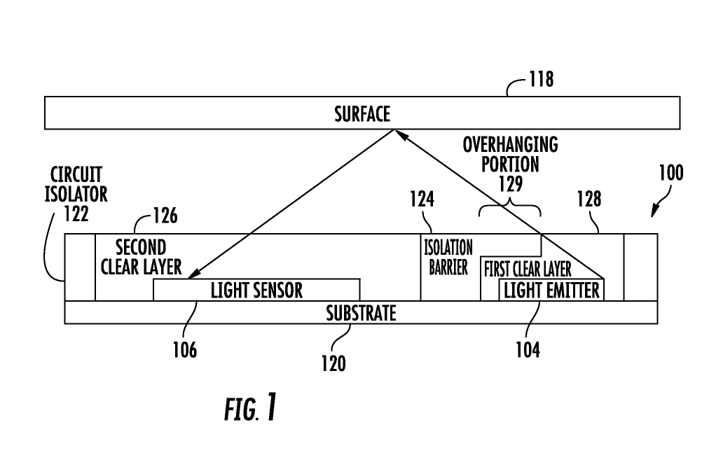

FIG. 1 is a diagram illustrating the operation of a proximity sensing device 100 fabricated with clear layer isolation. In certain embodiments, proximity sensing device 100 includes electronic devices that are isolated from one another and embedded within isolated clear layers. For example, proximity sensing device 100 includes a light emitter 104 embedded in a first clear layer 128 and a light sensor 106 embedded in a second clear layer 126 that is isolated from the first clear layer 128. The isolation of first clear layer 128 from second clear layer 126 prevents light from passing directly from first clear layer 128 to second clear layer 126 without first leaving proximity sensing device 100. Thus, the isolation prevents light emitted from light emitter 104 from reaching light sensor 106 via passage through a layer of device 100.

In certain embodiments, proximity sensing device 100 isolates first clear layer 128 from second clear layer 126 using an opaque isolation barrier 124 and an opaque substrate 120. Substrate 120 further supports light sensor 106 and light emitter 104. Isolation barrier 124 connects to substrate 120 and creates an opaque barrier between first clear layer 128 and second clear layer 126. Isolation barrier 124 prevents light emitted from light emitter 104 from propagating through the clear layer and contacting light sensor 106. Further, in some implementations, isolation barrier 124 includes an overhanging portion 129 that extends from isolation barrier 124 toward light emitter 104. The overhanging portion 129 prevents light emitted from light emitter 104 from contacting light sensor 106 without the presence of an external surface 118 near proximity sensing device 100. Further, device 100 further includes perimeter isolators 122. Perimeter isolators 122 isolate both the light sensor 106 and light emitter 104 from ambient sources of light. Perimeter isolators 122 also ensure that light emitted from light emitter 104 leaves in a substantially perpendicular direction from the top surface of device 100 and that light sensor 106 only receives light through the top surface of device 100.

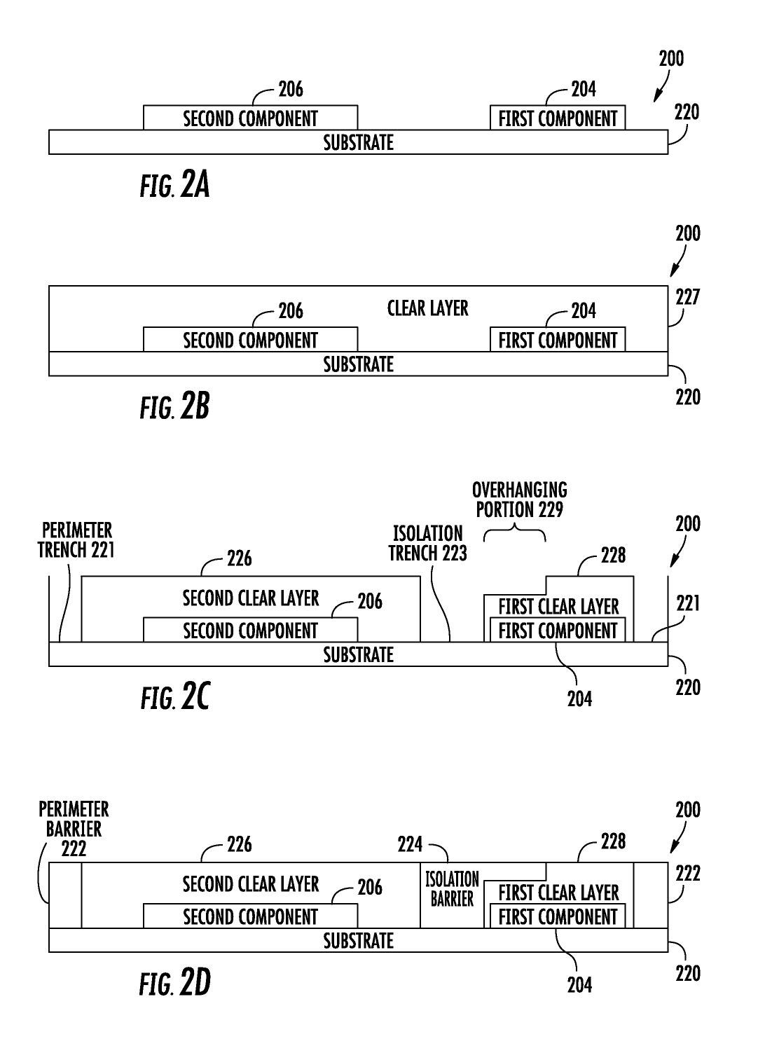

FIGS. 2A-2D are block diagrams illustrating the fabrication of a device 200 using clear layer isolation. In particular, FIG. 2A is a block diagram illustrating the placement of a first component 204 and a second component 206 on a substrate 220. Substrate 220 provides structural support for device 200. To fabricate the device, the fabrication process uses a substrate made from an opaque material to prevent light from traveling through substrate 220 between first component 204 and second component 206. Substrate 220 is at least one of a PCB substrate, a ceramic substrate, and a molded lead-frame. For example, when first component 204 is a light emitter and second component 206 is light sensor, light transmitted by the light emitter does not pass through substrate 220. Alternatively, first component 204 and second component 206 are other circuit components. To create the device, the process mounts first component 204 and second component 206 on substrate 220. For example, in some embodiments, first component 204 is a light emitting diode and second component 206 is a photodiode. When first component 204 and second component 206 are to be used in proximity sensing, the process places first component 204 and second component 206 at a desired distance apart from one another such that light emitted from first component 204 reflects off of a surface and is incident on second component 206. Further, the placing of first component 204 and second component 206 directly on substrate 220 before other fabrication steps allows the process to freely form wire bonds and other electrical connections without other structures and devices impeding the formation of the electrical connections between first component 204, second component 206, and substrate 220.

FIG. 2B is a block diagram illustrating one embodiment of the deposition of a clear layer in the fabrication of a device 200. In some embodiments, first component 204 and second component 206 either emit or receive light. To facilitate the passage of light from and to first component 204 and second component 206, a clear layer 227 is deposited over first component 204, second component 206, and over substrate 220. In certain embodiments, clear layer 227 is made from flowable materials such as epoxy based and silicon based materials. The process fabricates clear layer 227 using at least one of liquid casting, transfer molding, injection molding, fritting, low pressure molding, transfer molding, stencil printing, screen printing, and dispensing. Depositing clear layer 227 over the surface of substrate 220 allows clear layer 227 to firmly bond to substrate 220 and prevent delamination of clear layer 227 from substrate 220. In some implementations, pressure is applied to clear layer 227 to increase the strength of the bond between clear layer 227 and substrate 220.

FIG. 2C is a block diagram illustrating one embodiment of the formation of isolation trenches in clear layer 227. To isolate first component 204 from second component 206, the fabrication process forms an isolation trench 223 that extends through clear layer 227 between first component 204 and second component 206. Further, in some embodiments, the process forms a perimeter trench 221 around the perimeter of both first component 204 and second component 206. The fabrication process forms both isolation trench 223 and perimeter trench 221 through at least one of blade sawing, milling, laser ablation, etching, ashing, and the like. In some implementations, during the formation of isolation trench 223 and perimeter trench 221, the trenching method removes clear layer 227 to expose substrate 220 and further removes a portion of substrate 220. The formation of isolation trench 223 separates clear layer 227 into first clear layer 228 and second clear layer 226.

In a further embodiment, the process forms isolation trench 223 with a shape that is wider at the top of clear layer 227 than at the location where substrate 220 is exposed, such that an overhanging portion 229 extends from isolation trench 223 towards first component 204. For example, when isolation trench 223 is cut using a saw, the process cuts a trench entirely through clear layer 227. To make the trench wider at the top of clear layer 227, the process cuts overhanging portion 229 immediately next to the first trench portion. When the process cuts overhanging portion 229, the process cuts partially through clear layer 227, leaving a section of clear layer 227 under overhanging portion 229.

FIG. 2D is a block diagram illustrating the filling of isolation trench 223 and perimeter trench 221 to isolate first clear layer 228 from second clear layer 226. When the fabrication process forms isolation trench 223 between first component 204 and second component 206 and perimeter trench 221 around first component 204 and second component 206, an opaque deposit is placed within isolation trench 223 and perimeter trench 221 to form isolation barrier 224 and perimeter barrier 222 respectively. The opaque deposit includes materials such as a liquid crystal polymer and a transfer mold epoxy, which is a clear epoxy filled with silica based particles. Further, the process encapsulates the opaque material at an elevated temperature to impart a compressive stress on first clear layer 228 and second clear layer 226 to prevent delamination. In one implementation, opaque deposit is placed such that the top surface of isolation barrier 224 is aligned with the top surface of both first clear layer 228 and second clear layer 226. When the top surface of isolation barrier 224 is aligned with the top surface of first clear layer 228 and second clear layer 226, the exposed portions of first clear layer 228 and second clear layer 226 function as windows that allow light to pass through or exit the top surface of integrated circuit 200. Thus, when first component 204 is a light emitter, the emitted light exits through the top surface of first clear layer 228. Further, when second component 206 is a light sensor, light passes through the top surface of second clear layer 226 before being incident on the light sensor.

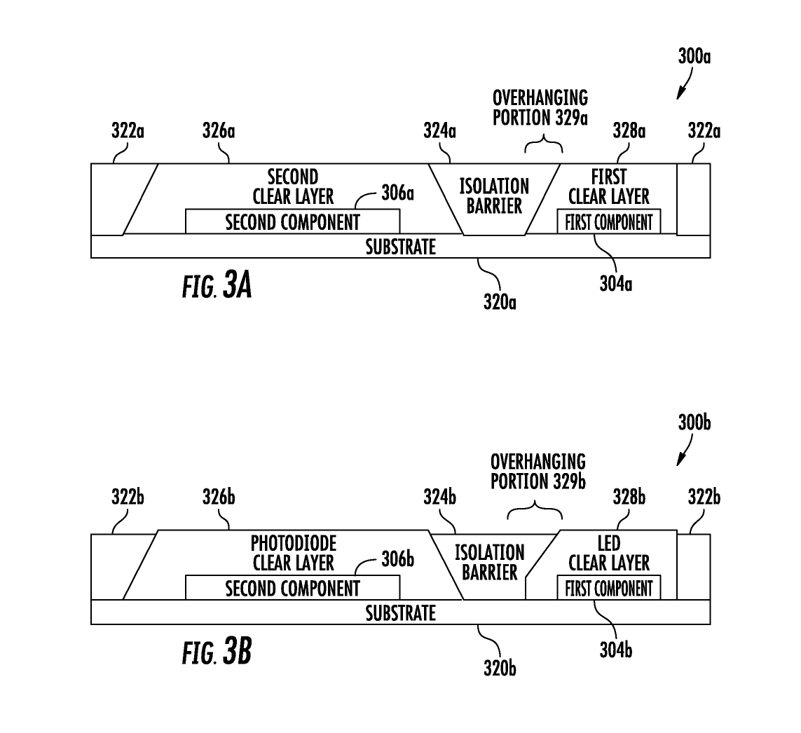

In conjunction with the shape of isolation trench 223 and isolation barrier 224 in FIGS. 2C and 2D, FIGS. 3A-3B illustrate different ways of forming an isolation barrier 324a-b between a first clear layer 328a-b and a second clear layer 326a-b. When forming isolation trenches, the process forms an isolation trench in such a way that when the trench is filled with opaque material to form isolation barrier 324a-b, the isolation barrier 324a-b includes an overhanging portion 329a-b that extends away from isolation barrier 324a-b to prevent the light emitted from a first component 304a-b from reaching a second component 306a-b without reflecting off of an external surface. To prevent emitted light from reaching second component 306a-b, the process forms a trench with a larger width near the top of first clear layer 328a-b and second clear layer 326a-b than the width of the trench where a substrate 320a-b is exposed. Further, when the process fills the trench with opaque material to form isolation barrier 324a-b, isolation barrier 324a-b will prevent delamination of both first clear layer 328a-b and second clear layer 326a-b.

In one embodiment, FIG. 3A is a block diagram illustrating a device 300a where an isolation trench was cut with slanted sides before being filled with opaque material to form isolation barrier 324a. Similar to isolation barrier 224 in FIG. 2, isolation barrier 324a includes an overhanging portion 329a that extends towards first component 304a. In a further embodiment, where the trench was cut into a portion of substrate 320a, isolation barrier 324 extends into substrate 320a. The extension of isolation barrier 324a into substrate 320a allows isolation barrier 324a to form a stronger bond with substrate 320a to prevent delamination of layers in integrated circuit 300a and eliminates light paths under isolation barrier 324a between first component 304a and second component 306a.

In a further embodiment, FIG. 3B is a block diagram illustrating a device 300b where an isolation trench was cut using a combination of a vertical and a slanted cut. In this implementation, the process makes a vertical cut to separate first clear layer 328b from second clear layer 326b. Further, the process forms an overhanging portion 329b by making a slanted cut through a portion of the thickness of first clear layer 328b such that resultant isolation trench has vertical sides proximate to substrate 320b and at least one slanted side near the top surface of first clear layer 328b. When the resultant isolation trench is filled with opaque material to form isolation barrier 324b, the overhanging portion 329b extends from isolation barrier 324b towards first component 304b. In another implementation, the isolation trench can be cut with two or more different slant angles and the perimeter barrier 322b is also slanted.

In other embodiments, as shown in FIG. 3B, the top surfaces of isolation barrier 324b and clear layers 326b and 328b are misaligned. For example, when the opaque material is deposited within the isolation trench, the top surface of isolation barrier 324b is lower than the top surfaces of clear layers 326b and 328b. Alternatively, the top surface of clear layers 326b and 328b are lower than the top surface of isolation barrier 24b.

As mentioned above, the above described fabrication processes help prevent delamination of a deposited clear layer. The process applies the clear layer over the entire surface of a supporting substrate. In some embodiments, the process applies pressure to promote the adhesion of the clear layer to a substrate. Also, in some embodiments, the opaque material selected to fill both the isolation trenches and perimeter trenches is selected such that the material has a better adhesion match with both the substrate material and the clear layer material, such as a liquid crystal polymer or a transfer mold epoxy. Further, by filling trenches in the clear layer with opaque material, the process forms isolation barriers with tapered walls having negative angles. The tapered walls of the isolation barriers lock the clear layer in place and prevent delamination of the substrate from the clear layer.

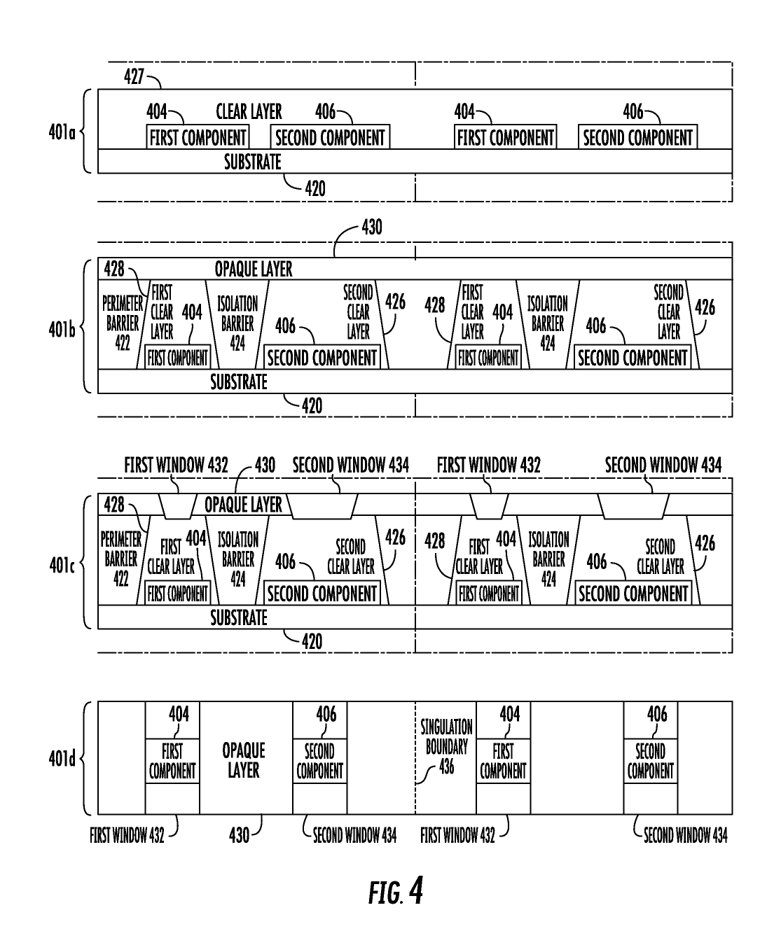

FIG. 4 illustrates one embodiment of the fabrication of multiple devices while isolating components of the devices in clear layers. At 401a, a fabrication process mounts multiple combinations of first component 404 and second component 406 on a substrate 420. The process then encapsulates the combinations of first component 404 and second component 406 within a clear layer 427 as described above in relation to FIGS. 2A-2B. At 401b, the process forms trenches in clear layer 427 to separate clear layer 427 into combinations of a first clear layer 428 and a second clear layer 426. Further, the process deposits opaque material within the trenches to form isolation barrier 424 and perimeter barrier 422. Further, in some embodiments, the process deposits an opaque layer 430 over the top of the isolation barrier 424, perimeter barrier 422, second clear layer 426, and first clear layer 428. In one embodiment, the processes uses the same material to form the opaque materials used to form barriers 422 and 424 and opaque layer 430.

In certain embodiments, at 401c, the process forms a first window 432 and a second window 434 by cutting through sections of opaque layer 430 to expose portions of first clear layer 428 and second clear layer 426. In some implementations, the opaque layer 430 covers portions of both first component 404 and second component 406 to prevent light emitted by first component 404 from being received by second component 406 without reflecting off of an external surface. In an alternative embodiment, the process forms windows 432 and 434 by covering portions of first clear layer 428 and second clear layer 426 with a stencil or a mask. The process then deposits an opaque layer over the integrated circuit and then removes the mask. The removal of the mask leaves portions of clear layers 426 and 428 exposed through windows 432 and 434 in opaque layer 430.

At 401d a top view of the device manufactured with first window 432 and second window 434 is shown. Opaque layer 430 is the top layer with windows 432 and 434 exposing first clear layer 428 and second clear layer 426. Window 432 and 434 can be a single window, a slit, and a plurality of slits. Further, the multiple devices are separated through sawing or other singulation techniques. Singulation line 436 represents an area where a saw or other cutting device can cut through the wafer to separate a plurality of conjoined devices into individual integrated circuits. As the opaque material that forms perimeter barrier 422 and opaque layer 430 surround first clear layer 428 and second clear layer 426 and are bound to substrate 420, the opaque material and opaque layer 430 prevent delamination of the clear layers 426 and 428 from substrate 420 during singulation of the panel into individual packages.

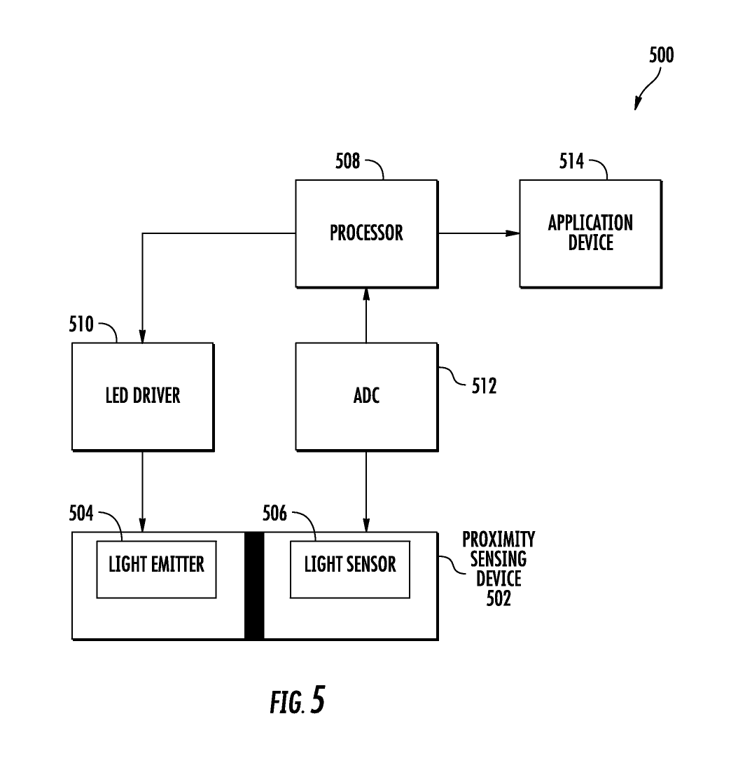

FIG. 5 is a block diagram illustrating one embodiment of a system 500 that implements a device formed using clear layer isolation. In particular, system 500 implements a proximity sensing device 502 that was formed using clear layer isolation. System 500 uses a light emitter 504 and light sensor 506 to sense the presence of objects that approach proximity sensing device 502. In certain embodiments, light emitter 504 is a light emitting diode and light sensor 506 is a photodiode. To control the transmission of light from light emitter 504, system 500 includes a processor 508 that transmits signals to a light emitter (LED) driver 510. The processor 508 instructs light emitter driver 510 when to transmit light through light emitter 504. Proximity sensing device 502 transmits a light from light emitter 504 to detect the presence of an external surface that reflects light back to proximity sensing device 502 such that the reflected light is incident on light sensor 506. When light emitted from light emitter 504 is incident on light sensor 506, light sensor 506 transmits an analog signal to an analog to digital converter (ADC) 512. ADC 512 converts the analog signal to a digital signal and transmits the digitized signal to processor 508. Processor 508 processes the digitized signal to determine whether an object was sensed by proximity sensing device 502. When processor 508 determines that proximity sensing device 502 received the reflected light transmitted by light emitter 504, processor 508 transmits the proximity determination to an application device 514. Application device 514 receives the proximity determination and performs a predetermined function based on the determination. In some embodiments, application device 514 includes mobile devices, televisions, computers, cameras, industrial equipment, and medical equipment. For example, when application device 514 is a touch screen mobile phone, system 500 indicates whether or not the screen of the mobile phone is close to a surface. When system 500 indicates that the screen is close to another surface like the face of a user, the mobile phone disables the touch screen to prevent the mobile phone from responding to contact with the users face. In an alternative embodiment, system 500 is an object avoidance system in a moving vehicle. When system 500 indicates that an object is within a certain distance, system 500 tries to avoid colliding with the sensed object.

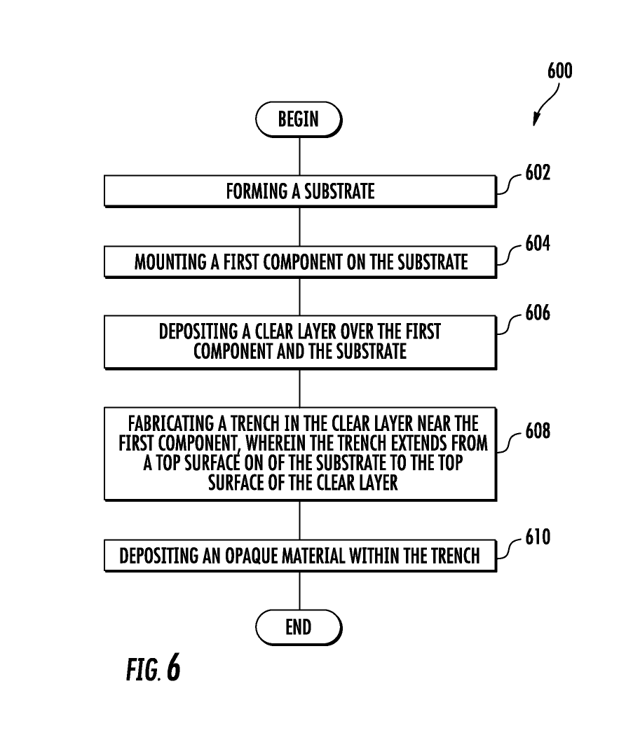

FIG. 6 is a flow diagram showing a method 600 for isolating electrical components in a clear layer. Method 600 commences at block 602 where a substrate is formed. At block 604, a first component is mounted to the substrate. At block 606, a clear layer is deposited over the first component and the substrate. At block 608, a trench is fabricated in the clear layer near the first component, wherein the trench extends from a top surface of the substrate to the top surface of the clear layer. At block 610, an opaque material is deposited within the trench.

Terms of relative position as used in this application are defined based on a plane parallel to the conventional plane or working surface of a wafer or substrate, regardless of the orientation of the wafer or substrate. The term “horizontal” or “lateral” as used in this application is defined as a plane parallel to the conventional plane or working surface of a wafer or substrate, regardless of the orientation of the wafer or substrate. The term “vertical” refers to a direction perpendicular to the horizontal. Terms such as “on,” “side” (as in “sidewall”), “higher,” “lower,” “over,” “top,” and “under” are defined with respect to the conventional plane or working surface being on the top surface of the wafer or substrate, regardless of the orientation of the wafer or substrate.

Although specific embodiments have been illustrated and described herein, it will be appreciated by those of ordinary skill in the art that any arrangement, which is calculated to achieve the same purpose, may be substituted for the specific embodiments shown. Therefore, it is manifestly intended that this invention be limited only by the claims and equivalents thereof.

What is claimed:

1. A method for optical isolation in a circuit, the method comprising:
mounting a first component on a substrate;
depositing a clear layer over the first component and the substrate;
fabricating a trench in the clear layer near the first component, wherein the trench extends from a top surface of the substrate to the top surface of the clear layer; and
depositing an opaque material within the trench.

2. The method of claim 1, wherein mounting the first component comprises forming electrical connections between the first component and the substrate.

3. The method of claim 1, wherein the first component is a light emitting diode.

4. The method of claim 1, further comprising mounting a second component on the substrate.

5. The method of claim 4, wherein the second component is a photodiode.

6. The method of claim 1, wherein forming the trench comprises cutting the trench such that the trench is wider near the top surface of the clear layer than at the top surface of the substrate.

7. The method of claim 6, wherein cutting the trench comprises forming an overhanging portion proximate to the trench, wherein the overhanging portion extends through a portion of the clear layer and extends away from the trench towards the first component.

8. The method of claim 1, wherein the trench extends into a portion of the substrate.

9. The method of claim 1, wherein the top surface of the opaque material deposited in the trench is level with the top surface of the clear layer

10. The method of claim 1, wherein the opaque material is deposited at an elevated temperature.

11. The method of claim 1, further comprising:
forming multiple circuits on the substrate; and
singulating the multiple circuits into individual circuits.

12. A method for optical isolation in a circuit, the method comprising:
depositing a clear layer over a first component, a second component, and a substrate, wherein the first component and the second component are located on the substrate;
forming an isolation trench in the clear layer between the first component and the second component, wherein the trench extends through the clear layer;
optically isolating the first component from the second component through the deposition of an opaque material within the trench;
depositing an opaque layer over the top surface of the circuit; and
forming a plurality of windows in the opaque layer, the windows allowing light to enter the clear layer over the first component and the second component.

13. The method of claim 12, further comprising:
forming multiple circuits on the substrate; and
singulating the multiple circuits into individual circuits.

14. The method of claim 12, wherein forming a plurality of windows comprises:
applying a mask over a region on the clear layer;
depositing the opaque material; and
removing the mask.

15. The method of claim 12, wherein the clear layer is deposited using at least one of:
liquid casting; and
molding.

16. The method of claim 12, wherein the opaque material is used to form the opaque layer.

17. The method of claim 12, wherein the first component is a light emitter.

18. The method of claim 12, wherein the second component is a light sensor.

19. A device with clear layer isolated components, the device comprising:
a substrate;
a first component mounted on the substrate, the first component encapsulated in a first clear layer;
a second component mounted on the substrate, the second component encapsulated in a second clear layer; and
an isolation barrier isolating the first component from the second component, wherein the isolation barrier is a trench filled with opaque material, the trench extending from a top surface of the substrate to a top surface of the first clear layer and the second clear layer, wherein the trench widens as it extends away from the top surface of the substrate.

20. The device of claim 19, wherein the isolation barrier further comprises an overhanging portion proximate to the trench, wherein the overhanging portion extends through a portion of the clear layer and extends away from the trench towards the first component;

21. The device of claim 19, wherein the substrate is opaque.

22. The device of claim 19, further comprising a perimeter barrier that surrounds the first component and the second component.

23. The device of claim 22, wherein the perimeter barrier further comprises an overhanging portion proximate to the isolation barrier, wherein the overhanging portion extends through a portion of the clear layer and extends away from the trench towards the first component and the second component.

24. A system for sensing proximity, the system comprising:
a proximity sensing circuit, the proximity sensing circuit comprising:
a substrate;
a light emitting diode mounted on the substrate, the light emitting diode encapsulated in a first clear layer, wherein the light emitting diode emits light through the first clear layer;
a photodiode mounted on the substrate, the photodiode encapsulated in a second clear layer, wherein the photodiode receives light through the second clear layer; and
an isolation barrier separating the light emitting diode from the photodiode, wherein the isolation barrier is a trench filled with opaque material, the trench extending from a top surface of the substrate to a top surface of the first clear layer and the second clear layer, wherein the trench widens as it extends away from the top surface of the substrate;
a light emitting diode driver configured to provide electrical signals to the light emitting diode;
an analog to digital converter configured to convert analog signals received from the photodiode and convert them to digital signals;
a processor configured to direct the light emitting diode driver to drive the light emitting diode and to receive digital signals from the analog to digital converter, the processor further configured to make a proximity determination based on the received digital signals; and
an application device that receives the proximity determination from the processor and performs a function based on the proximity determination.
